(19) United States
(12) Patent Application Publication
(10) Pub. No.: US 2025/0338720 A1
(43) Pub. Date: Oct. 30, 2025

(54) DISPLAY DEVICE AND MANUFACTURING METHOD THEREOF

(71) Applicant: Samsung Display Co., LTD., Yongin-si (KR)

(72) Inventors: Ju Won YOON, Yongin-si (KR); Jae Been LEE, Yongin-si (KR); Lok Gam JUNG, Yongin-si (KR)

(73) Assignee: Samsung Display Co., LTD., Yongin-si (KR)

(21) Appl. No.: 18/934,798

(22) Filed: Nov. 1, 2024

(30) Foreign Application Priority Data
Apr. 24, 2024 (KR) 10-2024-0054395

(51) Int. Cl. H10K 59/122; H10K 59/12; H10K 102/00

(52) U.S. Cl. CPC H10K 59/122; H10K 59/1201; H10K 2102/351

(57) ABSTRACT

Provided is a display device including a first electrode, a first pixel defining film disposed on the first electrode, a second pixel defining film disposed on the first pixel defining film, a void formed between an end of the first pixel defining film and an end of the second pixel defining film, a light emitting structure disposed on the first electrode, the first pixel defining film, and the second pixel defining film, and a second electrode disposed on the light emitting structure, wherein a thickness of a first area of the first pixel defining film overlapping the void is thicker than a thickness of a second area of the first pixel defining film non-overlapping the void.

### CROSS-REFERENCE TO RELATED APPLICATION

This application claims priority to and the benefit of Korean Patent Application No. 10-2024-0054395 filed in the Korean Intellectual Property Office on Apr. 24, 2024, the entire contents of which are incorporated herein by reference.

### BACKGROUND

### 1. Technical Field

The disclosure generally relates to a display device and a manufacturing method thereof. More particularly, the disclosure relates to a display device with improved reliability and a manufacturing method of the same.

### 2. Description of the Related Art

Recently, research and development for display devices are ongoing due to the growing interest in information displays. As the display devices are complicated, the need for reliable display devices is increased.

### SUMMARY

The disclosure provides a display device with improved reliability and a manufacturing method thereof.

Embodiments of the disclosure are not limited to the embodiment mentioned above, and other technical objects that are not mentioned may be clearly understood to a person of an ordinary skill in the art using the following description.

An embodiment provides a display device including: a first electrode; a first pixel defining film disposed on the first electrode; a second pixel defining film disposed on the first pixel defining film; a void formed between an end of the first pixel defining film and an end of the second pixel defining film; a light emitting structure disposed on the first electrode, the first pixel defining film, and the second pixel defining film; and a second electrode disposed on the light emitting structure, wherein a thickness of a first area of the first pixel defining film overlapping the void is thicker than a thickness of a second area of the first pixel defining film non-overlapping the void.

In the first area, the second pixel defining film may be spaced apart from the first pixel defining film in a thickness direction.

In the second area, the second pixel defining film may be in contact with the first pixel defining film.

The first pixel defining film may include a first opening exposing the first electrode, and the second pixel defining film may include a second opening exposing the first pixel defining film and the first electrode.

A width of the second opening may be greater than a width of the first opening in a plan view, and a width of the second opening is less than a width of the first electrode in a plan view.

A thickness of the void in a thickness direction may be about 50 Å to about 500 Å.

A lower surface of the void may be defined by the first pixel defining film.

An upper surface of the void may be defined by the second pixel defining film.

A side surface of the void may be defined by the second pixel defining film.

The light emitting structure may be at least partially separated by the void.

Another embodiment of the disclosure provides a manufacturing method of a display device, including: forming a first layer disposed on a first electrode; forming a sacrificial layer disposed on the first layer; forming a sacrificial pattern by etching the sacrificial layer; forming a second layer disposed on the first layer and the sacrificial pattern; forming a second pixel defining film by forming a second opening in the second layer to expose the sacrificial pattern; removing the sacrificial pattern through the second opening; and forming a first pixel defining film by forming a first opening in the first layer to expose the first electrode, wherein in the forming of the sacrificial pattern by etching the sacrificial layer, a portion of the first layer that does not overlap the sacrificial pattern is etched.

The second layer may be directly formed on the first layer exposed by the sacrificial pattern.

A width of the second opening may be smaller than a width of the sacrificial pattern in a plan view.

A width of the first opening may be smaller than a width of the second opening in a plan view.

In the removing of the sacrificial pattern, a void may be formed between an end of the first layer and an end of the second pixel defining film.

A thickness of the first pixel defining film overlapping the void in a thickness direction may be thicker than a thickness of the first pixel defining film that does not overlap the void in a thickness direction.

The manufacturing method of the display device may further include forming a light emitting structure disposed on the first electrode exposed by the first opening.

The light emitting structure may be at least partially separated by the void in a thickness direction.

The sacrificial layer may be made of aluminum or an aluminum alloy.

A thickness of the sacrificial layer in a thickness direction may be about 50 Å to about 500 Å.

Particularities of other embodiments are included in the detailed description and drawings.

According to the above-described embodiment, a void is formed between pixel defining films using a sacrificial pattern to separate light emitting structures, thereby minimizing a current leaking to adjacent sub-pixels, and prevent damage to an anode electrode.

Effects of embodiments of the disclosure are not limited by what is illustrated in the above, and more various effects are included in the present specification.

### BRIEF DESCRIPTION OF THE DRAWINGS

FIG. 1 illustrates a schematic block diagram of a display device according to an embodiment.

FIG. 2 illustrates a schematic block diagram of one of sub-pixels of FIG. 1 according to an embodiment.

FIG. 3 illustrates a schematic circuit diagram of the sub-pixel of FIG. 2 according to an embodiment.

FIG. 4 illustrates a schematic top plan view of a display panel of FIG. 1 according to an embodiment.

FIG. 5 illustrates an exploded schematic perspective view of a portion of the display panel of FIG. 4.

FIG. 6 illustrates a schematic top plan view of one of pixels of FIG. 5 according to an embodiment.

FIG. 7 illustrates a schematic cross-sectional view taken along line I-I′ of FIG. 6 according to an embodiment.

FIG. 8 illustrates a schematic cross-sectional view of a pixel defining film of FIG. 7 according to an embodiment.

FIG. 9 illustrates a schematic cross-sectional view of a light emitting structure included in one of first to third light emitting elements of FIG. 7 according to an embodiment.

FIG. 10 illustrates a schematic cross-sectional view of a light emitting structure included in one of first to third light emitting elements of FIG. 7 according to another embodiment.

FIG. 11 illustrates a schematic top plan view of one of pixels of FIG. 5 according to another embodiment.

FIG. 12 illustrates a schematic top plan view of one of pixels of FIG. 5 according to another embodiment.

FIG. 13 illustrates a schematic block diagram of a display system according to an embodiment.

FIG. 14 illustrates a schematic perspective view of an application example of the display system of FIG. 13.

FIG. 15 illustrates a schematic head-mounted display device of FIG. 14 worn by a user.

FIG. 16 to FIG. 26 illustrate schematic cross-sectional views of process steps of a manufacturing method of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

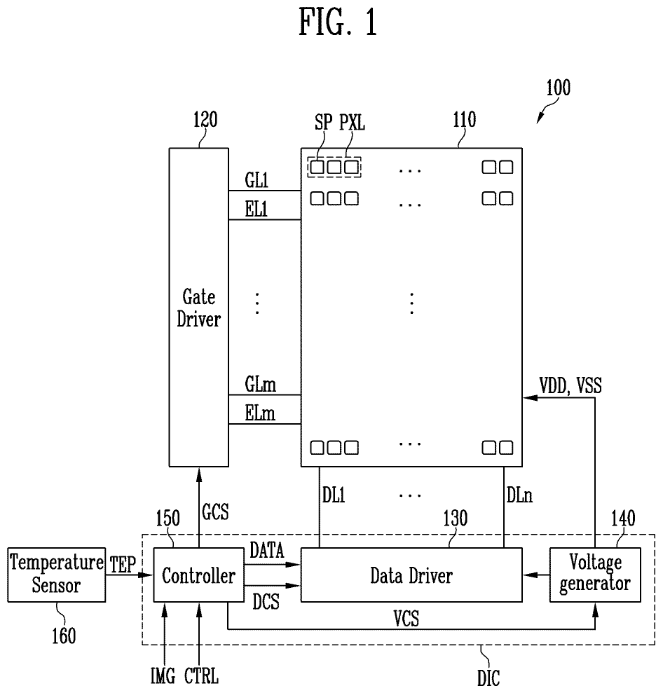

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention. FIG. 1 illustrates a schematic block diagram of a display device according to an embodiment.

Referring to FIG. 1, a display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element to generate light. Accordingly, each of the sub-pixels SP may generate light of a specific color respectively, such as red, green, blue, cyan, magenta, yellow, or the like. Two or more of the sub-pixels SP may configure one pixel PXL. For example, as shown in FIG. 1, three sub-pixels SP may configure one pixel PXL. In another example, less than three sub-pixels SP may configure a pixel PXL. In still another example, more than three sub-pixels SP may configure one pixel PXL. For example, rows of the sub-pixels SP are arranged in a second direction DR2, and columns of the sub-pixels SP are arranged in a first direction DR1.

The gate driver 120 may be connected to the sub-pixels SP arranged in the second direction DR2 through the first to m-th gate lines GL1 to GLm. The gate driver 120 may output gate signals to the first to m-th gate lines GL1 to GLm in response to a gate control signal GCS received from a controller 150. The gate control signal GCS may include a start signal indicating the start of each frame, a horizontal synchronization signal for outputting gate signals in synchronization with the timing at which data signals are applied, and the like.

In some embodiments, first to m-th light emitting control lines EL1 to ELm connected to the sub-pixels SP in the second direction DR2 may be further provided. For example, the gate driver 120 may include a light emitting control driver configured to control the first to m-th light emitting control lines EL1 to ELm, and the light emitting control driver may operate under the control of the controller 150.

The gate driver 120 may be disposed on one side of the display panel 110. For example, the gate driver 120 may be disposed on the left side of the display panel 110. However, embodiments are not limited thereto. For example, the gate driver 120 may be divided into two or more physically and/or logically separated drivers, and the drivers may be disposed on a side of the display panel 110 and another side of the display panel 110 opposite to the one side. As described above, the gate driver 120 may be disposed around the display panel 110 in various forms according to the embodiments.

The data driver 130 may be connected to the sub-pixels SP arranged in a column direction through the first to n-th data lines DL1 to DLn. The data driver 130 may receive image data (DATA) and a data control signal DCS from the controller 150. The data driver 130 may operate in response to the data control signal DCS. The data control signal DCS may include a source start pulse, a source shift clock, a source output enable signal, and the like.

The data driver 130 may use voltages from the voltage generator 140 to apply data signals having grayscale voltages corresponding to the image data (DATA) to the first to n-th data lines DL1 to DLn. In case that a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image may be displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to constituent elements of the display device 100. For example, the voltage generator 140 may generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level which is lower than the first power voltage VDD. In other embodiments, the first power voltage VDD or the second power voltage VSS may be provided by an external source.

The voltage generator 140 may generate various voltages. For example, the voltage generator 140 may generate an initialization voltage applied to the sub-pixels SP. For example, during a sensing operation to sense electrical characteristics of transistors and/or light emitting elements of the sub-pixels SP, a selectable reference voltage may be applied to the first to n-th data lines DL1 to DLn, and the voltage generator 140 may generate the reference voltage.

The controller 150 may control various operations of the display device 100. The controller 150 may receive input image data IMG and a control signal CTRL for controlling the display of the input image data received from the outside. The controller 150 may provide the gate control signal GCS to the gate driver 120 and may provide the data control signal DCS and the voltage control signal VCS to the data driver 130 in response to the control signal CTRL.

The controller 150 may convert the input image data IMG to be suitable for the display device 100 or the display panel 110 to output the image data DATA. The controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. The driver integrated circuit DIC may be disposed on a side of the display panel 110. The driver integrated circuit DIC may be disposed on the bottom side of the display panel 110. However, embodiments are not limited thereto. For example, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 may sense a surrounding temperature of the display device 100 to generate temperature data TEP representing the sensed temperature to the controller 150. The temperature sensor 160 may be disposed to be adjacent to the display panel 110 and/or the driver integrated circuit DIC. However, embodiments are not limited thereto.

The controller 150 may control various operations of the display device 100 in response to the temperature data TEP. The controller 150 may adjust the luminance of an image outputted from the display panel 110 in response to the temperature data TEP. For example, the controller 150 may control the data signals and the first and second power voltages VDD and VSS by controlling components such as the data driver 130 and/or the voltage generator 140.

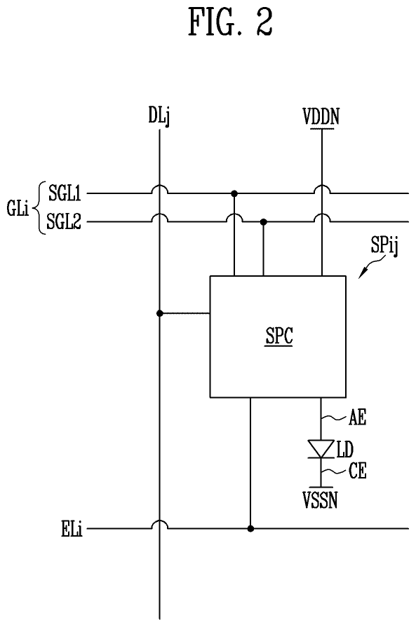

FIG. 2 illustrates a schematic block diagram of one of sub-pixels of FIG. 1 according to an embodiment. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) may be illustrated as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may transmit the first power voltage VDD of FIG. 1, and the second power voltage node VSSN may transmit the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th light emitting control line ELi among the first to m-th light emitting control lines EL1 to ELm of FIG. 1, and a j-th data line DLj among the first to n-th data lines DL1 to DLn of FIG. 1. The sub-pixel circuit SPC may be connected to at least one gate line, at least one light emitting control line, and at least one data line. The sub-pixel circuit SPC may control the light emitting element LD according to signals received through these signal lines.

The sub-pixel circuit SPC may operate in response to a gate signal received through the i-th gate line GLi. The i-th gate line GLi may include one or more sub-gate lines. In the embodiments, as shown in FIG. 2, the i-th gate line GLi may include a first sub-gate line SGL1 extending in the first direction DR1 and a second sub-gate line SGL2 which is parallel to the first sub-gate line SGL1 and extending in the first direction DR1. The sub-pixel circuit SPC may operate in response to gate signals received through the first and second sub-gate lines SGL1 and SGL2. As such, in case that the i-th gate line GLi includes two or more sub-gate lines, the sub-pixel circuit SPC may operate in response to gate signals received through the corresponding sub-gate lines.

The sub-pixel circuit SPC may operate in response to a light emitting control signal received through the i-th light emitting control line ELi. In the embodiments, the i-th light emitting control line ELi may include one or more sub-light emitting control lines. When the i-th light emitting control line ELi includes two or more sub-light emitting control lines, the sub-pixel circuit SPC may operate in response to light emitting control signals received through the corresponding sub-light emitting control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light emitting control signal received through the i-th light emitting control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

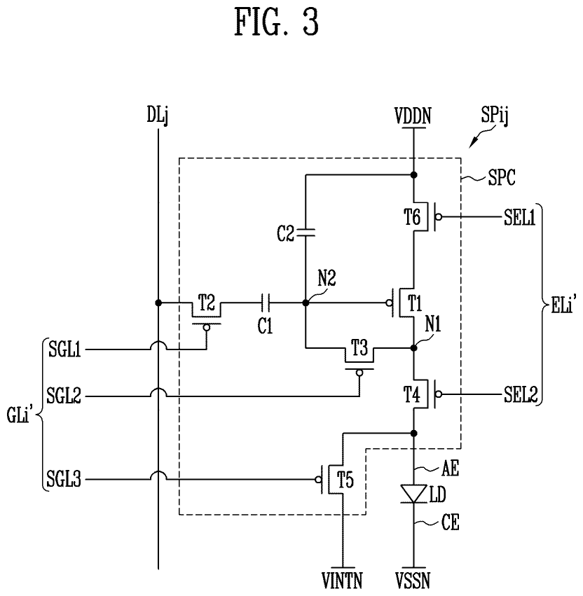

FIG. 3 illustrates a schematic circuit diagram of the sub-pixel of FIG. 2 according to an embodiment.

Referring to FIG. 3, the sub-pixel SPij may include a sub-pixel circuit SPC and a light emitting element LD.

The sub-pixel circuit SPC may be connected to an i-th gate line GLi′, an i-th light emitting control line ELi′, and a j-th data line DLj. Compared to the i-th gate line GLi of FIG. 2, the i-th gate line GLi′ may further include a third sub-gate line SGL3 which is parallel to the first and second sun-gate lines SGL1, SGL2 and extending in the first direction DR1. Compared to the i-th light emitting control line ELi of FIG. 2, the i-th light emitting control line ELi′ may include a first sub-light emitting control line SEL1 and a second sub-light emitting control line SEL2 which is parallel to the first sub-light emitting control line SEL1.

The sub-pixel circuit SPC may include first to sixth transistors T1 to T6 and first and second capacitors C1 and C2.

The first transistor T1 may be electrically connected between the first power voltage node VDDN and a first node N1. A gate of the first transistor T1 is electrically connected to a second node N2, and accordingly, the first transistor T1 may be turned on according to a voltage level of the second node N2. The first transistor T1 may be referred to as a driving transistor.

The second transistor T2 may be electrically connected between the j-th data line DLj and the second node N2. A gate of the second transistor T2 is electrically connected to the first sub-gate line SGL1, and accordingly, the second transistor T2 may be turned on in response to the gate signal of the first sub-gate line SGL1. The second transistor T2 may be referred to as a switching transistor.

The third transistor T3 may be electrically connected between the first node N1 and the second node N2. A gate of the third transistor T3 is electrically connected to the second sub-gate line SGL2, and accordingly, the third transistor T3 may be turned on in response to the gate signal of the second sub-gate line SGL2.

The fourth transistor T4 may be electrically connected between the first node N1 and the anode electrode AE of the light emitting element LD. A gate of the fourth transistor T4 is electrically connected to the second sub-light emitting control line SEL2, and accordingly, the fourth transistor T4 may be turned on in response to the light emitting control signal of the second sub-light emitting control line SEL2.

The fifth transistor T5 may be electrically connected between the anode electrode AE of the light emitting element LD and an initialization voltage node VINTN. The initialization voltage node VINTN may transmit an initialization voltage. The initialization voltage may be provided by the voltage generator 140 of FIG. 1. In other embodiments, the initialization voltage may be provided by an external source to the display device 100. A gate of the fifth transistor T5 is electrically connected to the third sub-gate line SGL3, and accordingly, the fifth transistor T5 may be turned on in response to the gate signal of the third sub-gate line SGL3.

The sixth transistor T6 may be electrically connected between a first power voltage node VDDN and the first transistor T1. A gate of the sixth transistor T6 is electrically connected to the first sub-light emitting control line SEL1, and accordingly, the sixth transistor T6 may be turned on in response to the light emitting control signal of the first sub-light emitting control line SEL1.

The first capacitor C1 may be electrically connected between the second transistor T2 and the second node N2. The second capacitor C2 may be electrically connected between the first power voltage node VDDN and the second node N2.

As described above, the sub-pixel circuit SPC may include the first to sixth transistors T1 to T6 and the first and second capacitors C1 and C2. However, embodiments are not limited thereto. The sub-pixel circuit SPC may be implemented as one of various circuits including a plurality of transistors and one or more capacitors. For example, the sub-pixel circuit SPC may include two transistors and one capacitor. According to the embodiments of the sub-pixel circuit SPC, the number of sub-gate lines included in the i-th gate line GLi′ and the number of sub-light emitting control lines included in the i-th light emitting control line ELi′ may vary.

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be replaced with an N-type transistor.

The first to sixth transistors T1 to T6 may include an amorphous silicon semiconductor, a monocrystalline silicon semiconductor, a polycrystalline silicon semiconductor, and an oxide semiconductor.

The light emitting element LD may include the anode electrode AE, the cathode electrode CE, and the light emitting layer. The light emitting layer may be disposed between the anode electrode AE and the cathode electrode CE. After the data signal transmitted through the j-th data line DLj is reflected in the voltage of the second node N2, the fourth and sixth transistors T4 and T6 may be turned on in case that the light emitting control signals of the first and second sub-light emitting control lines SEL1 and SEL2 are enabled to a low level. The first transistor T1 may be turned on according to the voltage of the second node N2, and accordingly, a current may flow from the first power voltage node VDDN to the second power voltage node VSSN. The light emitting element LD may emit light depending on the amount of current flowing.

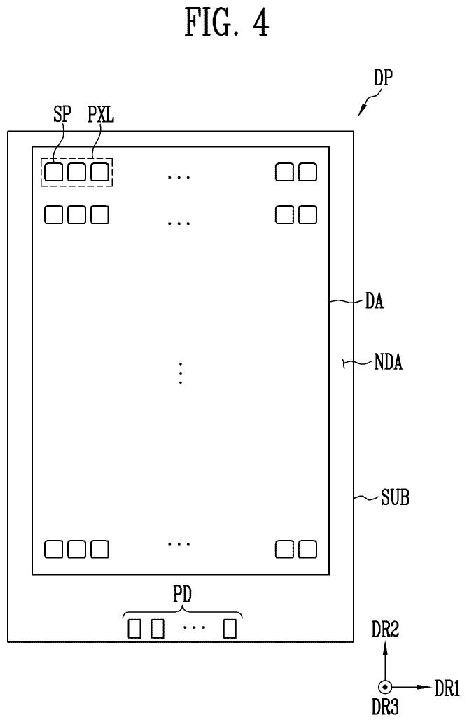

FIG. 4 illustrates a schematic top plan view of an embodiment of a display panel of FIG. 1.

Referring to FIG. 4, an embodiment DP of the display panel 110 of FIG. 1 may include a display area DA and a non-display area NDA which is disposed adjacent to the display area DA. The display panel DP may display an image through the display area DA. For example, the non-display area NDA may surround the display area DA.

The display panel DP may include a substrate SUB, sub-pixels SP, and pads PD.

In case that the display panel DP is used as a display screen for a head mounted display (HMD), a virtual reality (VR) device, a mixed reality (MR) device, or an augmented reality (AR) device, the display panel DP may be positioned very close to the user's eyes. For example, the sub-pixels SP with relatively high integration may be required. In order to increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLED on silicon (OLEDOS) display device.

The sub-pixels SP may be disposed in the display area DA on the substrate SUB. The sub-pixels SP may be arranged in a matrix format along the first direction DR1 and the second direction DR2 that intersects the first direction DR1. However, embodiments are not limited thereto. For example, the sub-pixels SP may be arranged in a zigzag form along first direction DR1 and second direction DR2. For example, the sub-pixels SP may be disposed in a pentile shape. The first direction DR1 may be a row direction, and the second direction DR2 may be a column direction.

Two or more of the plurality of sub-pixels SP may configure one pixel PXL.

A constituent element to control the sub-pixels SP may be disposed in the non-display area NDA on the substrate SUB. For example, wires connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, and the temperature sensor 160 in FIG. 1 may be integrated in the non-display area NDA of the display panel DP. The gate driver 120 of FIG. 1 may be mounted on the display panel DP, and may be disposed in the non-display area NDA. In other embodiments, the gate driver 120 may be implemented as an integrated circuit separated from the display panel DP. The temperature sensor 160 may be disposed in the non-display area NDA to detect the temperature of the display panel DP.

The pads PD may be disposed in the non-display area NDA on the substrate SUB. The pads PD may be disposed on the bottom portion of the display panel DP. However, the embodiments are not limited thereto. The pads PD may be electrically connected to the sub-pixels SP through wires. For example, the pads PD may be connected to the sub-pixels SP through the first to n-th data lines DL1 to DLn.

The pads PD may interface the display panel DP to other constituent elements of the display device 100 (see FIG. 1). In embodiments, voltages and signals required for operations of constituent elements included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in case that the gate driver 120 is mounted on the display panel DP, the gate control signal GCS may be transmitted from the driver integrated circuit DIC to the gate driver 120 through the pads PD.

The circuit board may be electrically connected to the pads PD by using a conductive adhesive member such as an anisotropic conductive film. For example, the circuit board may be a flexible printed circuit board (FPCB) or a flexible film made of a flexible material. The driver integrated circuit DIC may be mounted on the circuit board to be electrically connected to the pads PD.

The display area DA may have various shapes. The display area DA may have a closed-loop shape including sides of a straight line and/or a curved line. For example, the display area DA may have shapes such as a rectangular shape, a triangular shape, a circular shape, a semicircular, an elliptical shape, and any polygonal shape. The display area DA may have curved corners.

The display panel DP may have a flat display surface. In other embodiments, the display panel DP may have a display surface that is at least partially round. The display panel DP may be bendable, foldable, or rollable. In these cases, the display panel DP and/or the substrate SUB may include materials with flexible properties.

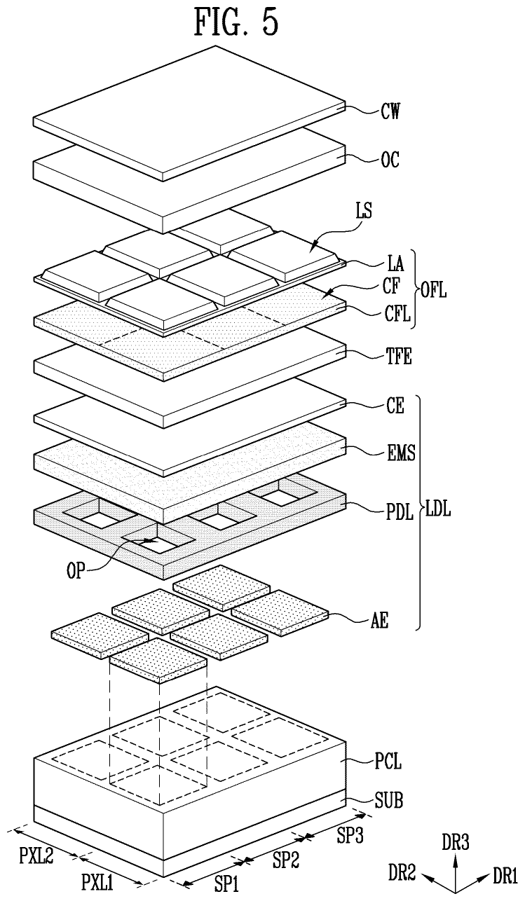

FIG. 5 illustrates a schematic exploded perspective view of a portion of the display panel of FIG. 4. In FIG. 5, for clear and concise description, a portion of the display panel DP corresponding to two pixels PXL1 and PXL2 among the pixels PXL of FIG. 4 is schematically shown. Portions of the display panel DP corresponding to the remaining pixels may be similarly configured.

Referring to FIG. 4 and FIG. 5, each of the first and second pixels PXL1 and PXL2 may include first to third sub-pixels SP1 to SP3. However, embodiments are not limited thereto. For example, each of the first and second pixels PXL1 and PXL2 may include more than three sub-pixels or less than three sub-pixels.

In FIG. 5, the first to third sub-pixels SP1 to SP3 may have rectangular shapes and have the same sizes in case that viewed in the third direction DR3 crossing the first and second directions DR1 and DR2. However, embodiments are not limited thereto. The first to third sub-pixels SP1 to SP3 may have various surface shapes.

The display panel DP may include a substrate SUB, a pixel circuit layer PCL, a light emitting element layer LDL, an encapsulation layer TFE, an optical functional layer OFL, an overcoat layer OC, and a cover window CW. As depicted in FIG. 5, the substrate SUB, the pixel circuit layer PCL, the light emitting element layer LDL, the encapsulation layer TFE, the optical functional layer OFL, the overcoat layer OC, and the cover window CW may be sequentially stacked in the third direction DR3 (e.g., thickness direction).

The substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOI) layer. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, wires, and the like.

The conductive patterns may include copper, but embodiments are not limited thereto.

The circuit elements may include the sub-pixel circuit SPC (see FIG. 2) for each of first to third sub-pixels SP1 to SP3. The sub-pixel circuit SPC may include transistors and one or more capacitors. Each transistor may include a semiconductor portion including a source area, a drain area, and a channel area, and a gate electrode overlapping the semiconductor portion. In case that the substrate SUB is provided as a silicon substrate, the semiconductor portion may be included in the substrate SUB, and the gate electrode may be included in the pixel circuit layer PCL as the conductive pattern of the pixel circuit layer PCL. In case that the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer therebetween.

The wires of the pixel circuit layer PCL may include signal lines connected to each of the first to third sub-pixels SP1 to SP3, for example, a gate line, a light emitting control line, and a data line. The wires may further include the wire connected to the first power voltage node VDDN of FIG. 2. The wires may further include the wire connected to the second power voltage node VSSN of FIG. 2.

The light emitting element layer LDL may include anode electrodes AE, a pixel defining film PDL, a light emitting structure EMS, and a cathode electrode CE. The light emitting element layer LDL may be disposed on the pixel circuit layer PCL.

For example, the anode electrodes AE may be disposed on the pixel circuit layer PCL. The anode electrodes AE may be electrically connected to circuit elements of the pixel circuit layer PCL. The anode electrodes AE may include an opaque conductive material capable of reflecting light, but embodiments are not limited thereto.

The pixel defining film PDL may be disposed on the anode electrodes AE. The pixel defining film PDL may include an opening OP exposing a portion of each of the anode electrodes AE. For example, the opening OP exposing a portion of each of the anode electrodes AE may be defined in the pixel defining film PDL. The opening OP of the pixel defining film PDL may be understood as light emitting areas corresponding to the first to third sub-pixels SP1 to SP3, respectively.

The pixel defining film PDL may include an inorganic material. For example, the pixel defining film PDL may include a plurality of stacked inorganic layers. For example, the pixel defining film PDL may include a silicon oxide (SiOx) and/or a silicon nitride (SiNx). In other embodiments, the pixel defining film PDL may include an organic material. However, the material of the pixel defining film PDL is not limited thereto.

The light emitting structure EMS may be disposed on the anode electrodes AE exposed by the opening OP of the pixel defining film PDL. The light emitting structure EMS may include a light emitting layer to generate light, an electron transport layer to transport electrons, and a hole transport layer to transport holes.

The light emitting structure EMS may fill the opening OP of the pixel defining film PDL, and may be disposed entirely on an upper portion of the pixel defining film PDL. The light emitting structure EMS may extend across the first to third sub-pixels SP1 to SP3. For example, at least some of the functional layers in the light emitting structure EMS may be separated (disconnected) or bent at the boundaries between the first to third sub-pixels SP1 to SP3. However, embodiments are not limited thereto. For example, portions of the light emitting structure EMS corresponding to the first to third sub-pixels SP1 to SP3 are separated from each other, and each of the separated light emitting structures EMS may be disposed in the opening OP of the pixel defining film PDL.

The cathode electrode CE may be disposed on the light emitting structure EMS. The cathode electrode CE may extend across the first to third sub-pixels SP1 to SP3 along the first direction DR1 and the second direction DR2. As such, the cathode electrode CE may be provided as a common electrode for the first to third sub-pixels SP1 to SP3.

The cathode electrode CE may be a thin metal layer with a thickness sufficient to transmit light emitted from the light emitting structure EMS. The cathode electrode CE may be made of a metallic material or a transparent conductive material to have a relatively thin thickness. The cathode electrode CE may include at least one of various transparent conductive materials including an indium tin oxide, an indium zinc oxide, an indium tin zinc oxide, an aluminum zinc oxide, a gallium zinc oxide, a zinc tin oxide, and a gallium tin oxide. In other embodiments, the cathode electrode CE may include at least one of silver (Ag), magnesium (Mg), and a mixture thereof. However, the material of the cathode electrode CE is not limited thereto.

One of the anode electrodes AE, the portion of the light emitting structure EMS overlapping the one of the anode electrodes AE, and the portion of the cathode electrode CE overlapping the one of the anode electrodes AE may be understood to configure one light emitting element LD (see FIG. 2). Each of the light emitting elements of the first to third sub-pixels SP1 to SP3 may include one anode electrode AE, a portion of the light emitting structure EMS overlapping one anode electrode AE, and a portion of the cathode electrode CE overlapping one anode electrode AE. In each of the first to third sub-pixels SP1 to SP3, holes injected from the anode electrode AE and electrons injected from the cathode electrode CE are transported into the light emitting layer of the light emitting structure EMS to form excitons, and in case that the excitons transition from the excited state to the ground state, light may be generated. The luminance of light may be determined depending on the amount of current flowing through the light emitting layer. Depending on the configuration of the light emitting layer, the wavelength range of the generated light may be determined.

An encapsulation layer TFE may be disposed on the cathode electrode CE. The encapsulation layer TFE may cover the light emitting element layer LDL and/or the pixel circuit layer PCL. The encapsulation layer TFE may be configured to prevent oxygen and/or moisture from penetrating into the light emitting element layer LDL. The encapsulation layer TFE may include a structure in which one or more inorganic films and one or more organic films are alternately stacked. For example, the inorganic film may include a silicon nitride, a silicon oxide, or a silicon oxynitride (SiOxNy). For example, the organic film may include an organic insulating material such as an acrylic resin, an epoxy resin, a phenol resin, a polyamide resin, a polyimide resin, an unsaturated polyesters resin, a polyphenylenethers resin, a polyphenylenesulfides resin, or a benzocyclobutene. However, the materials of the organic film and the inorganic film of the encapsulation layer TFE are not limited thereto.

The encapsulation layer TFE may further include a thin film containing an aluminum oxide (AlOx) in order to improve the encapsulation efficiency of the encapsulation layer TFE. The thin film containing an aluminum oxide may be disposed on the upper surface of the encapsulation layer TFE facing the optical functional layer OFL and/or the lower surface of the encapsulation layer TFE facing the light emitting element layer LDL.

The thin film containing the aluminum oxide may be formed through atomic layer deposition (ALD). However, embodiments are not limited thereto. The encapsulation layer TFE may further include a thin film made of at least one of various materials suitable for improving the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may selectively output light in a wavelength range or color corresponding to each sub-pixel by filtering light emitted from the light emitting structure EMS. The color filter layer CFL includes color filters CF respectively corresponding to the first to third sub-pixels SP1 to SP3, and each of the color filters CF may pass light in a wavelength range corresponding to the sub-pixel. For example, a color filter corresponding to the first sub-pixel SP1 may pass red light, but may block green and blue lights, a color filter corresponding to the second sub-pixel SP2 may pass green light, but block red and blue lights, and a color filter corresponding to the third sub-pixel SP3 may pass blue light, but blocks red and green lights. At least some of the color filters CF may be omitted according to light emitted from the light emitting structure EMS of each sub-pixel.

The lens array LA may be disposed on the color filter layer CFL. The lens array LA may include lenses LS respectively corresponding to the first to third sub-pixels SP1 to SP3. Each of the lenses LS may improve light output efficiency by outputting light emitted from the light emitting structure EMS in an intended path. The lens array LA may have a relatively high refractive index. For example, the lens array LA may have a higher refractive index than the overcoat layer OC. The lenses LS may include an organic material. In another embodiments, the lenses LS may include an acrylic material. However, the material of the lenses LS is not limited thereto.

Compared to the opening OP of the pixel defining film PDL, at least some of the color filters CF of the color filter layer CF and at least some of the lenses LS of the lens array LA may be shifted in a direction parallel to a plane defined by the first and second directions DR1 and DR2. For example, in the center area of the display area DA, the center of the color filter and the center of the lens may be aligned or overlapped with the center of the opening OP of the corresponding pixel defining film PDL in case that viewed in the third direction DR3. For example, in the central area of the display area DA, the opening OP of the pixel defining film PDL may completely overlap the corresponding color filter of the color filter layer CF and the corresponding lens of the lens array LA. In an area of the display area DA adjacent to the non-display area NDA, the center of the color filter and the center of the lens may be shifted in a planar direction from the center of the opening OP of the corresponding pixel defining film PDL in case that viewed in the third direction DR3. For example, in an area of the display area DA adjacent to the non-display area NDA, the opening OP of the pixel defining film PDL may partially overlap the corresponding color filter of the color filter layer CFL and the corresponding lens of the lens array LA. Accordingly, in the center of the display area DA, light emitted from the light emitting structure EMS may be efficiently outputted in the normal direction of the display surface. Light emitted from the light emitting structure EMS at the outside of the display area DA may be efficiently outputted in a direction inclined by a predetermined angle with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign substances such as dust and moisture. For example, the overcoat layer OC may include at least one of an inorganic insulating film and an organic insulating film. For example, the overcoat layer OC may include an epoxy resin, but embodiments are not limited thereto. The overcoat layer OC may have a lower refractive index than the lens array LA.

The cover window CW may be disposed on the overcoat layer OC. The cover window CW may protect lower layers thereof. The cover window CW may have a higher refractive index than the overcoat layer OC. The cover window CW may include glass, but embodiments are not limited thereto. For example, the cover window CW may be an encapsulation glass configured to protect constituent elements disposed thereunder. In other embodiments, the cover window CW may be omitted.

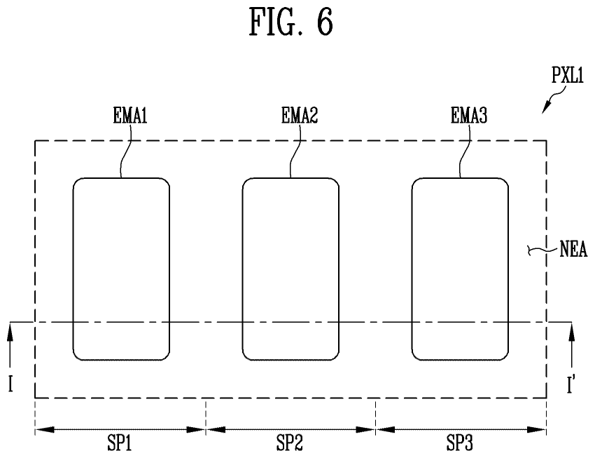

FIG. 6 illustrates a schematic top plan view of one of pixels of FIG. 5 according to an embodiment. For a clear and concise description in FIG. 6, the first pixel PXL1 among the first and second pixels PXL1 and PXL2 of FIG. 5 may be schematically illustrated. The remaining pixels may be configured similarly to the first pixel PXL1.

Referring to FIG. 5 and FIG. 6, a first pixel PXL1 may include the first to third sub-pixels SP1 to SP3 disposed in the first direction DR1.

The first sub-pixel SP1 may include a first light emitting area EMA1 and a non-light emitting area NEA around the first light emitting area EMA1. The second sub-pixel SP2 may include a second light emitting area EMA2 and a non-light emitting area NEA around the second light emitting area EMA2. The third sub-pixel SP3 may include a third light emitting area EMA3 and a non-light emitting area NEA around the third light emitting area EMA3.

The first light emitting area EMA1 may be an area in which light is emitted from a portion of the light emitting structure EMS (see FIG. 5) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3. As described with reference to FIG. 5, each light-emitting area may be understood as the opening OP of the pixel defining film PDL corresponding to each of the first to third sub-pixels SP1 to SP3.

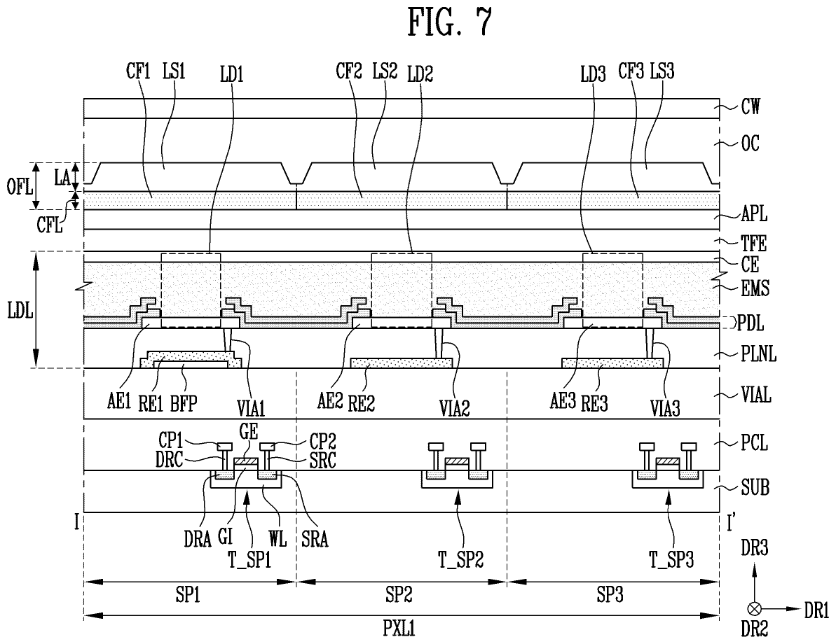

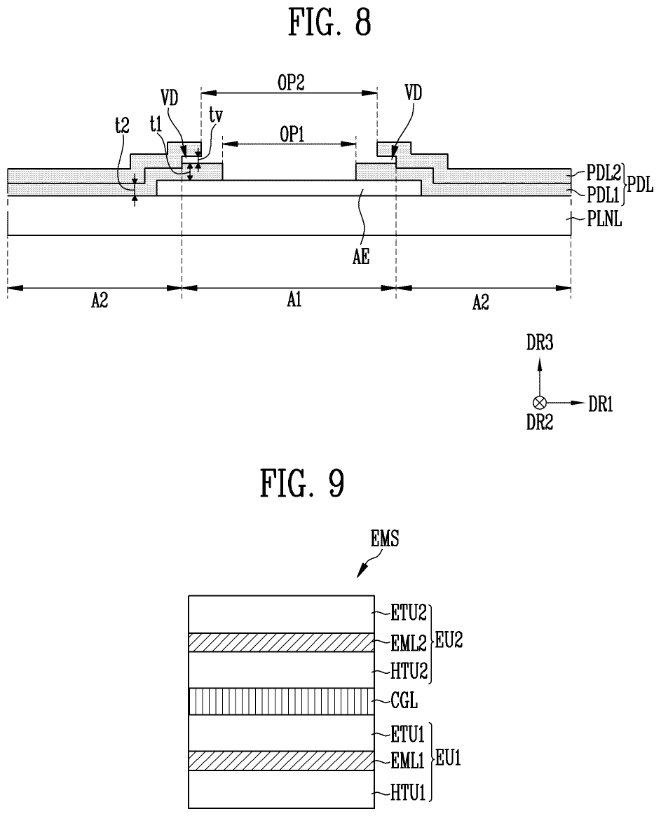

FIG. 7 illustrates a schematic cross-sectional view taken along line I-I′ of FIG. 6 according to an embodiment. FIG. 8 illustrates a schematic cross-sectional view of a pixel defining film of FIG. 7 according to an embodiment.

Referring to FIG. 7, the substrate SUB and the pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements for each of the first to third sub-pixels SP1 to SP3. For example, the substrate SUB and the pixel circuit layer PCL may include a transistor T SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 7, for clear and concise description, one of the transistors of each sub-pixel is shown and the remaining circuit elements are omitted.

The transistor T_SP1 of the first sub-pixel SP1 may include a source area SRA, a drain area DRA, and a gate electrode GE.

The source area SRA and the drain area DRA may be disposed within the substrate SUB. A well WL formed through an ion injection process is disposed in the substrate SUB, and the source area SRA and the drain area DRA may be spaced apart from each other within the well WL. The area between the source area SRA and the drain area DRA within the well WL may be defined as a channel area.

The gate electrode GE disposed between the source area SRA and the drain area DRA overlaps the channel area in the third direction DR3 (e.g., thickness direction), and may be disposed on the pixel circuit layer PCL. The gate electrode GE may be separated from the well WL or the channel area by an insulating material such as a gate insulating layer GI. The gate electrode GE may include a conductive material.

A plurality of layers included in the pixel circuit layer PCL include insulating layers and conductive patterns disposed between the insulating layers, and the conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are electrically connected to other circuit elements and/or wires, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include circuit elements for each of the first to third sub-pixels SP1 to SP3.

A via layer VIAL may be disposed on the pixel circuit layer PCL. The via layer VIAL covers the pixel circuit layer PCL, and may have an overall flat surface. The via layer VIAL may be a flatten step on the pixel circuit layer PCL. The via layer VIAL may include at least one of a silicon oxide (SiOx), a silicon nitride (SiNx), and a silicon carbon nitride (SiCN), but embodiments are not limited thereto.

The light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining film PDL, a light emitting structure EMS, and a cathode electrode CE.

On the via layer VIAL, the first to third reflective electrodes RE1 to RE3 may be disposed in the first to third sub-pixels SP1 to SP3, respectively. Each of the first to third reflective electrodes RE1 to RE3 may be electrically connected to a circuit element disposed on the pixel circuit layer PCL through a via penetrating the via layer VIAL.

The first to third reflective electrodes RE1 to RE3 may function as full mirrors that reflect light emitted from the light emitting structure EMS toward the display surface (or the cover window CW). The first to third reflective electrodes RE1 to RE3 may include metallic materials suitable for reflecting light. The first to third reflective electrodes RE1 to RE3 may include at least one of aluminum (A1), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom, but embodiments are not limited thereto.

A connection electrode may be disposed below each of the first to third reflective electrodes RE1 to RE3. The connection electrode may improve the electrical connection characteristics between the corresponding reflective electrode and the circuit element of the pixel circuit layer PCL. The connection electrode may have a multi-layered structure. The multi-layered structure may include titanium (Ti), a titanium nitride (TiN), a tantalum nitride (TaN), and the like, but embodiments are not limited thereto. A corresponding reflective electrode may be disposed between the multiple layers of the connecting electrode.

A buffer pattern BFP may be disposed below at least one of the first to third reflective electrodes RE1 to RE3. The buffer pattern BFP may include an inorganic material such as a silicon carbon nitride, but embodiments are not limited thereto. By disposing the buffer pattern BFP, the height of the corresponding reflective electrode in the third direction DR3 may be adjusted. For example, as depicted in FIG. 7, the buffer pattern BFP may be disposed between the first reflective electrode RE1 and the via layer VIAL to adjust the height of the first reflective electrode RE1. However, in another example, the buffer pattern BFP may be disposed between the second reflective electrode RE2 and the via layer VIAL to adjust the height of the second reflective electrode RE2. In another example, the buffer pattern BFP may be disposed between the third reflective electrode RE3 and the via layer VIAL to adjust the height of the third reflective electrode RE3.

The first to third reflective electrodes RE1 to RE3 may function as full mirrors, and the cathode electrode CE may function as a half mirror. Light emitted from the light emitting layer of the light emitting structure EMS may be amplified at least partially by reciprocating between the reflective electrode and the cathode electrode CE, and the amplified light may be outputted through the cathode electrode CE. As such, the distance between each reflective electrode and the cathode electrode CE may be understood as the resonance distance for the light emitted from the light emitting layer of the corresponding light emitting structure EMS.

The first sub-pixel SP1 may have a shorter resonance distance along the third direction DR3 than other sub-pixels due to the buffer pattern BFP. The resonance distance adjusted in this way may allow light in a specific wavelength range (for example, red color) to be effectively and efficiently amplified. Accordingly, the first sub-pixel SP1 may effectively and efficiently output light in the corresponding wavelength range.

In FIG. 7, the buffer pattern BFP is shown to be provided in the first sub-pixel SP1 and not in the second and third sub-pixels SP2 and SP3, but the embodiments are not limited thereto. The buffer pattern may be also provided in at least one of the second and third sub-pixels SP2 and SP3, so that the resonance distance of at least one of the second and third sub-pixels SP2 and SP3 may be adjusted. For example, the first to third sub-pixels SP1 to SP3 may correspond to red, green, and blue, respectively, the distance between the first reflective electrode RE1 and the cathode electrode CE may be shorter than the distance between the second reflective electrode RE2 and the cathode electrode CE, and the distance between the second reflective electrode RE2 and the cathode electrode CE may be shorter than the distance between the third reflective electrode RE3 and the cathode electrode CE.

To planarize between the first to third reflective electrodes RE1 to RE3, the planarization layer PLNL may be disposed on the via layer VIAL and the first to third reflective electrodes RE1 to RE3. The planarization layer PLNL may entirely cover the first to third reflective electrodes RE1 to RE3 and the via layer VIAL, and may have a flat surface. In another embodiments, the planarization layer PLNL may be omitted.

The first to third anode electrodes AE1 to AE3 respectively overlapping the first to third reflective electrodes RE1 to RE3 may be disposed on the planarization layer PLNL. The first to third anode electrodes AE1 to AE3 may have shapes similar to the first to third light emitting areas EMA1 to EMA3 of FIG. 6 in case that viewed in the third direction DR3. The first to third anode electrodes AE1 to AE3 may be respectively connected to the first to third reflective electrodes RE1 to RE3. The first anode electrode AE1 may be connected to the first reflective electrode RE1 through the first via VIA1 penetrating the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

The first to third anode electrodes AE to AE3 may include at least one of transparent conductive materials such as an indium tin oxide (ITO), an indium zinc oxide (IZO), a zinc oxide (ZnOx), an indium gallium zinc oxide (IGZO), and an indium tin zinc oxide (ITZO). However, the materials of the first to third anode electrodes AE1 to AE3 are not limited thereto. For example, the first to third anode electrodes AE1 to AE3 may include a titanium nitride.

Insulating layers for adjusting a height of one or more of the first to third anode electrodes AE1 to AE3 may be further provided. The insulating layers may be disposed between one or more of the first to third anode electrodes AE1 to AE3 and the corresponding reflective electrodes. For example, the planarization layer PLNL and/or the buffer pattern BFP may be omitted. For example, the first to third sub-pixels SP1 to SP3 may respectively correspond to red, green, and blue, the distance between the first anode electrode AE1 and the cathode electrode CE may be shorter than the distance between the second anode electrode AE2 and the cathode electrode CE, and the distance between the second anode electrode AE2 and the cathode electrode CE may be shorter than the distance between the third anode electrode AE3 and the cathode electrode CE.

The pixel defining film PDL may be disposed on some of the first to third anode electrodes AE1 to AE3 and the planarization layer PLNL. The pixel defining film PDL may include an opening exposing a portion of each of the first to third anode electrodes AE1 to AE3. An opening exposing a portion of each of the first to third anode electrodes AE1 to AE3 may be defined in the pixel defining film PDL. The opening of the pixel defining film PDL may define the light emitting area for each of the first to third sub-pixels SP1 to SP3. As such, the pixel defining film PDL may be disposed in the non-light emitting area NEA of FIG. 6 to define the first to third light emitting areas EMA1 to EMA3 of FIG. 6.

As depicted in FIG. 8, the pixel defining film PDL may include a plurality of inorganic insulating layers. For example, the pixel defining film PDL may include a first pixel defining film PDL1 and a second pixel defining film PDL2 disposed on the first pixel defining layer PDL1. Each of the first pixel defining film PDL1 and the second pixel defining film PDL2 may include at least one of a silicon oxide (SiOx) and a silicon nitride (SiNx).

The first pixel defining film PDL1 may be disposed on the anode electrode AE. The first pixel defining film PDL1 may be directly disposed on the anode electrode AE and may be in direct contact with the anode electrode AE. The first pixel defining film PDL I may include a first opening OP1 at least partially exposing the anode electrode AE. A width of the first opening OP1 in the first direction DR1 may be smaller than a width of the anode electrode AE in the first direction DR1.

The second pixel defining film PDL2 may be disposed on the first pixel defining film PDL1. The second pixel defining film PDL2 may be directly disposed on the first pixel defining film PDL1 and may be in direct contact with the first pixel defining film PDL1. The second pixel defining film PDL2 may include a second opening OP2 that at least partially exposes the first pixel defining film PDL1 and the anode electrode AE. A width of the second opening OP2 in the first direction DR1 may be greater than a width of the first opening OP1 in the first direction DR1, but may be smaller than a width of the anode electrode AE in the first direction DR1.

The first pixel defining film PDL1 and the second pixel defining film PDL2 may be at least partially spaced apart from each other in the third direction DR3. A void VD may be formed between the first pixel defining film PDL1 and the second pixel defining film PDL2. For example, an end of the first pixel defining film PDL1 and an end of the second pixel defining film PDL2 may be spaced apart from each other in the third direction DR3 so that the void VD may be formed in a space in which the first pixel defining film PDL1 and the second pixel defining film PDL2 are spaced apart from each other. The void VD may overlap the first pixel defining film PDL1, the second pixel defining film PDL2, and the anode electrode AE in the third direction DR3.

A lower surface of the void VD may be defined by the first pixel defining film PDL1. For example, the lower surface of the void VD may be a portion of an upper surface of the first pixel defining film PDL1. A side surface of the void VD may be defined by the second pixel defining film PDL2. For example, a side surface of the void VD may be a portion of the lower surface of the second pixel defining film PDL2. A distance in the first direction DR1 from a side surface to another side surface of the void VD may be greater than a width in the first direction DR1 of the first opening OP1. The distance in the first direction DR1 from a side surface to another side surface of the void VD may be greater than a width in the first direction DR1 of the second opening OP2. The distance in the first direction DR1 from one side surface to the other side surface of the void VD may be smaller than a width in the first direction DR1 of the anode electrode AE. The upper surface of the void VD may be defined by the second pixel defining film PDL2. For example, the upper surface of the void VD may be a portion of the lower surface of the second pixel defining film PDL2. A thickness tv of the void VD in the third direction DR3 may be around 50 Å to around 500 Å, but is not limited thereto.

A thickness t1 in the third direction DR3 of the first area A1 of the first pixel defining film PDL1 overlapping the void VD may be different from a thickness t2 in the third direction DR3 of the second area A2 of the first pixel defining film PDL1 non-overlapping the void VD. The thickness t1 in the third direction DR3 of the first area A1 of the first pixel defining film PDL1 overlapping the void VD may be thicker than the thickness t2 in the third direction DR3 of the second area A2 of the first pixel defining film PDL1 non-overlapping the void VD. For example, in the process of forming the void VD, the second area A2 of the first pixel defining film PDL1 may be partially etched so that the thickness t2 of the second area A2 in the third direction DR3 may be formed to be thinner than the thickness t1 of the first area A1 in the third direction DR3. This process will be described in detail with reference to FIG. 19.

In the first area A1 overlapping the void VD, the first pixel defining film PDL1 and the second pixel defining film PDL2 may be spaced apart from each other in the third direction DR3. In the second area A2 that does not overlap the void VD, the second pixel defining film PDL2 may be directly disposed on the first pixel defining film PDL1. In the second area A2 that does not overlap the void VD, the second pixel defining film PDL2 may be in contact with the first pixel defining film PDL1.

The void VD may cause a discontinuity in the light emitting structure EMS between the first to third sub-pixels SP1 to SP3. Some of a plurality of layers stacked in the light emitting structure EMS may be disconnected or bent by the void VD. For example, at least one charge generation layer included in the light emitting structure EMS may be disconnected in the void VD. As described above, due to the void VD, the portions of the light emitting structure EMS included in the first to third sub-pixels SP1 to SP3 may be at least partially separated. Accordingly, in case that the display panel DP operates, the current leaking from each of the first to third sub-pixels SP1 to SP3 to the neighboring sub-pixel through the layers included in the light-emitting structure EMS may decrease. Accordingly, the first to third light emitting elements LD1 to LD3 may operate with relatively high reliability.

Referring back to FIG. 7, the light emitting structure EMS may be disposed on the anode electrode AE and the pixel defining film PDL. The light emitting structure EMS may be disposed on the anode electrodes AE exposed by the pixel defining film PDL. The light emitting structure EMS may be entirely disposed across the first to third sub-pixels SP1 to SP3. Some or all of the plurality of layers included in the light emitting structure EMS may be separated or bent between the first to third sub-pixels SP1 to SP3 by the void VD.

The cathode electrode CE may be disposed on the light emitting structure EMS. The cathode electrode CE may be provided commonly for the first to third sub-pixels SP1 to SP3. The cathode electrode CE may function as a half mirror that partially transmits and partially reflects light emitted from the light emitting structure EMS.

The cathode electrode CE may be provided commonly for the first to third sub-pixels SP1 to SP3.

The first anode electrode AE1, the portion of the light emitting structure EMS overlapping the first anode electrode AE1 along the third direction DR3, and the portion of the cathode electrode CE overlapping the first anode electrode AE1 along the third direction DR3 may configure the first light emitting element LD1. The second anode electrode AE2, the portion of the light emitting structure EMS overlapping the second anode electrode AE2 along the third direction DR3, and the portion of the cathode electrode CE overlapping the second anode electrode AE2 along the third direction DR3 may configure the second light emitting element LD2. The third anode electrode AE3, the portion of the light emitting structure EMS overlapping the third anode electrode AE3 along the third direction DR3, and the portion of the cathode electrode CE overlapping the third anode electrode AE3 along the third direction DR3 may configure the third light emitting element LD3.

The encapsulation layer TFE may be disposed on the cathode electrode CE. The encapsulation layer TFE may prevent oxygen and/or moisture from penetrating into the light emitting element layer LDL.

The optical functional layer OFL may be disposed on the encapsulation layer TFE. The optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may pass light in different wavelength ranges. For example, the first to third color filters CF1 to CF3 may pass red, green, and blue colored light, respectively.

The first to third color filters CF1 to CF3 may overlap the first to third sub-pixels SP1 to SP3. In another embodiments, the first to third color filters CF1 to CF3 may be spaced apart from each other, and a black matrix may be provided between the first to third color filters CF1 to CF3. For example, the black matrix may be provided between the first color filter CF1 and the second color filter CF2, may be provided between the second color filter CF2 and the third color filter CF3, and may be provided between the first color filter CF1 and the third color filter CF3. For example, the first to third color filters CF1 to CF3 may partially overlap the first to third sub-pixels SP1 to SP3.

The lens array LA may be disposed on the color filter layer CFL. The lens array LA may include first to third lenses LS1 to LS3 respectively corresponding to the first to third sub-pixels SP1 to SP3. The first to third lenses LS1 to LS3 may improve light output efficiency by outputting the light emitted from the first to third light emitting elements LD1 to LD3, respectively, along an intended path.

FIG. 9 illustrates a schematic cross-sectional view of an embodiment of a light emitting structure included in one of first to third light emitting elements of FIG. 7.

Referring to FIG. 9, the light emitting structure EMS may have a tandem structure in which first and second light emitting portions EU1 and EU2 are stacked. The light emitting structure EMS may be substantially the same in each of the first to third light emitting elements LD1 to LD3 of FIG. 7.

Each of the first and second light emitting portions EU1 and EU2 may include at least one light emitting layer that generates light according to a current applied thereto. The first light emitting portion EU1 may include a first light emitting layer EML1, a first electron transport portion ETU1, and a first hole transport portion HTU1. The first light emitting layer EML1 may be interposed between the first electron transport portion ETU1 and the first hole transport portion HTU1. The second light emitting portion EU2 may include a second light emitting layer EML2, a second electron transport portion ETU2, and a second hole transport portion HTU2. The second light emitting layer EML2 may be interposed between the second electron transport portion ETU2 and the second hole transport portion HTU2.

Each of the first and second hole transport portions HTU1 and HTU2 may include at least one of a hole injection layer and a hole transport layer, and may further include a hole buffer layer, an electron blocking layer, or the like as needed. The first and second hole transport portions HTU1 and HTU2 may have the same configuration or different configurations.

Each of the first and second electron transport portions ETU1 and ETU2 may include at least one of an electron injection layer and an electron transport layer, and may further include an electron buffer layer and a hole blocking layer as needed. The first and second electron transport portions ETU1 and ETU2 may have the same configuration or different configurations.

A connection layer, which may be provided in the form of a charge generation layer CGL, may be interposed between the first light emitting portion EU1 and the second light emitting portion EU2 to connect them to each other. The charge generation layer CGL may have a stacked structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide-based metal, or a combination thereof. However, embodiments are not limited thereto.

The first light emitting layer EML1 and the second light emitting layer EML2 may generate light of different colors. The light emitted from each of the first light emitting layer EML1 and the second light emitting layer EML2 may be mixed to be recognized as white light. For example, the first light emitting layer EML1 may generate blue-colored light, and the second light emitting layer EML2 may generate yellow-colored light. The second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. For example, an intermediate layer configured to perform a function of transporting holes and/or preventing transport of electrons may be further disposed between the first and second sub-light emitting layers. In other embodiments, the first light emitting layer EML1 and the second light emitting layer EML2 may generate light of the same color.

The light emitting structure EMS may be formed through a vacuum deposition method, an inkjet printing method, or the like, but embodiments are not limited thereto.

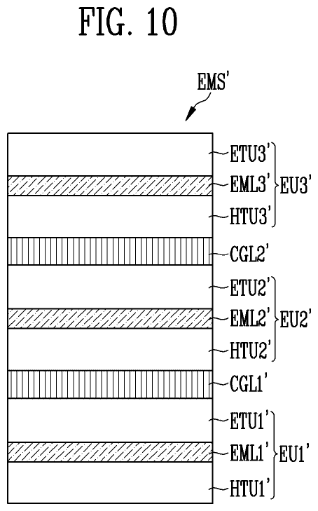

FIG. 10 illustrates a schematic cross-sectional view of a light emitting structure included in one of first to third light emitting elements of FIG. 7 according to another embodiment.

Referring to FIG. 10, a light emitting structure EMS′ may have a tandem structure in which first to third light emitting portions EU1′ to EU3′ are stacked. The light emitting structure EMS′ may be configured to be substantially the same in each of the first to third light emitting elements LD1 to LD3 of FIG. 7.

Each of the first to third light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be interposed between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be interposed between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be interposed between the third electron transport portion ETU3′ and the third hole transport portion HTU3′.

Each of the first to third hole transport portions HTU1′ to HTU3′ may include at least one of a hole injection layer and a hole transport layer, and may further include a hole buffer layer, an electron blocking layer, or the like as needed. The first to third hole transport portions HTU1′ to HTU3′ may have the same configuration or different configurations.

Each of the first to third electron transport portions ETU1′ to ETU3′ may include at least one of an electron injection layer and an electron transport layer, and may further include an electron buffer layer and a hole blocking layer as needed. The first to third electron transport portions ETU1′ to ETU3′ may have the same configuration or different configurations.

A first charge generation layer CGL1′ may be interposed between the first light emitting portion EU1′ and the second light emitting portion EU2′. A second charge generation layer CGL2′ may be interposed between the second light emitting portion EU2′ and the third light emitting portion EU3′.

The first to third light emitting layers EML1′ to EML3′ may generate light of different colors. Light emitted from each of the first to third light emitting layers EML1′ to EML3′ may be mixed to be viewed as white light. For example, the first light emitting layer EML1′ may generate light of a blue color, the second light emitting layer EML2′ may generate light of a green color, and the third light emitting layer EML3′ may generate light of a red color. In other embodiments, two or more of the first to third light emitting layers EML1′ to EML3′ may generate light of the same color.

Unlike FIG. 9 and FIG. 10, the light emitting structure EMS of FIG. 7 may include one light emitting portion in each of the first to third light emitting elements LD1 to LD3. For example, the light emitting portions respectively included in the first to third light emitting elements LD1 to LD3 may be configured to emit light of different colors. For example, the light emitting portion of the first light emitting element LD1 may emit a red-colored light, the light emitting portion of the second light emitting element LD2 may emit a green-colored light, and the light emitting portion of the third light emitting element LD3 may emit a blue-colored light. For example, the light emitting portions of the first to third sub-pixels SP1 to SP3 are separated from each other, and each of them may be disposed in the opening OP of the pixel defining film PDL. For example, at least some of the color filters CF1 to CF3 may be omitted.

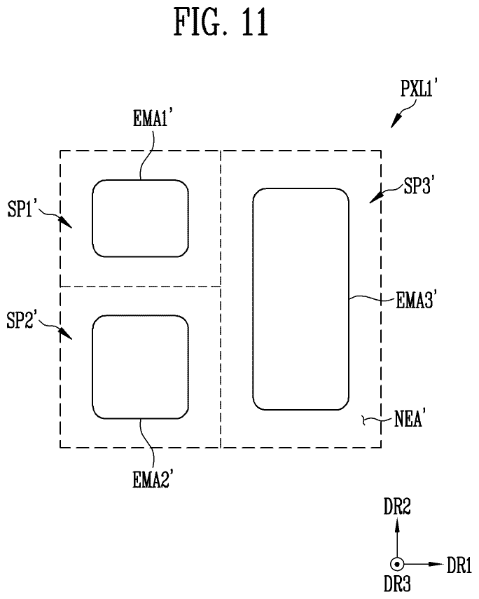

FIG. 11 illustrates a schematic top plan view of one of pixels of FIG. 5 according to another embodiment.

Referring to FIG. 11, a first pixel PXL1′ may include first to third sub-pixels SP1′ to SP3′.

The first sub-pixel SP1′ may include a first light emitting area EMA1′ and a non-light emitting area NEA′ around the first light emitting area EMA1′. The second sub-pixel SP2′ may include a second light emitting area EMA2′ and a non-light emitting area NEA′ around the second light emitting area EMA2′. The third sub-pixel SP3′ may include a third light emitting area EMA3′ and a non-light emitting area NEA′ around the third light emitting area EMA3′.

The first sub-pixel SP1′ and the second sub-pixel SP2′ may be spaced apart from each other in the second direction DR2. The third sub-pixel SP3′ may be spaced apart from each of the first and second sub-pixels SP1′ and SP2′ in the first direction DR1.

The second sub-pixel SP2′ may have a larger area than the first sub-pixel SP1′, and the third sub-pixel SP3′ may have a larger area than the second sub-pixel SP2′. Accordingly, the second light emitting area EMA2′ may have a larger area than the first light emitting area EMA1′, and the third light emitting area EMA3′ may have a larger area than the second light emitting area EMA2′. However, embodiments are not limited thereto. For example, in another embodiments, the first and second sub-pixels SP1′ and SP2′ may have substantially the same area, and the third sub-pixel SP3′ may have a larger area than each of the first and second sub-pixels SP1′ and SP2′. As such, the areas of the first to third sub-pixels SP1′ to SP3′ may be variously changed depending on embodiments.

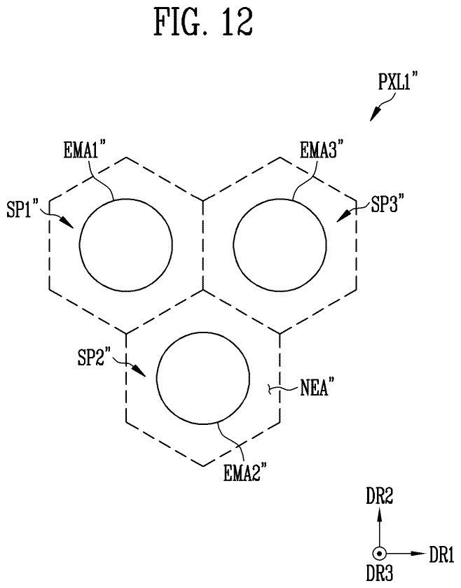

FIG. 12 illustrates a schematic top plan view of one of pixels of FIG. 5 according to another embodiment.

Referring to FIG. 12, the first sub-pixel SP1″ may include a first light emitting area EMA1″ and a non-light emitting area NEA″ around the first light emitting area EMA1″. The second sub-pixel SP2″ may include a second light emitting area EMA2″ and a non-light emitting area NEA″ around the second light emitting area EMA2″. The third sub-pixel SP3″ may include a third light emitting area EMA3″ and a non-light emitting area NEA″ around the third light emitting area EMA3″.

The first to third sub-pixels SP1″ to SP3″ may have polygonal shapes in case that viewed in the third direction DR3. For example, the shapes of the first to third sub-pixels SP1″ to SP3″ may be hexagonal.

The first to third light emitting areas EMA1″ to EMA3″ may have circular shapes in case that viewed in the third direction DR3. However, embodiments are not limited thereto. For example, each of the first to third light emitting areas EMA1″ to EMA3″ may have a polygonal shape.

The first and third sub-pixels SP1″ and SP3″ may be spaced apart from each other in the first direction DR1. The second sub-pixel SP2″ may be disposed in a direction (or a diagonal direction) inclined by an acute angle with respect to the second direction DR2 with respect to the first sub-pixel SP1″.

The dispositions of the sub-pixels illustrated in FIGS. 6, 11, and 12 are merely examples, and embodiments are not limited thereto.

Each pixel may include two or more sub-pixels, the sub-pixels may be variously disposed, each of the sub-pixels may have various shapes, and each of its light emitting areas may also have various shapes.

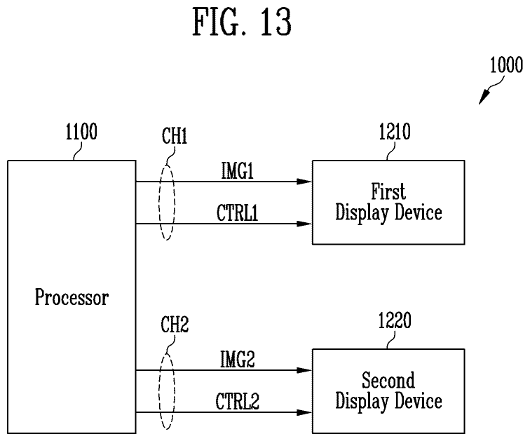

FIG. 13 illustrates a schematic block diagram of a display system according to an embodiment.

Referring to FIG. 13, the display system 1000 may include a processor 1100 and one or more display devices 1210 and 1220.

The processor 1100 may perform various tasks and calculations. The processor 1100 may include an application processor, a graphics processor, a microprocessor, a central processing unit (CPU), and the like. The processor 1100 may be connected to and step other constituent elements of the display system 1000 through a bus system.

As depicted in FIG. 13, the display system 1000 may include the first and second display devices 1210 and 1220. The processor 1100 may be connected to the first display device 1210 through a first channel CH1 and connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be similar to the display device 100 described with reference to FIG. 1. For example, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be similar to the display device 100 described with reference to FIG. 1. For example, the second image data IMG2 and the second control signal CTRL2 may be provided as the input image data IMG and the control signal CTRL of FIG. 1, respectively.

The display system 1000 may include a computing system providing image display functions such as a portable computer, a mobile phone, a smart phone, a tablet personal computer (PC), a smart watch, a watch phone, a portable multimedia player (PMP), a navigation system, and an ultra mobile personal computer (UMPC). The display system 1000 may include at least one of a head-mounted display device (HMD), a virtual reality (VR) device, a mixed reality (MR) device, and an augmented reality (AR) device.

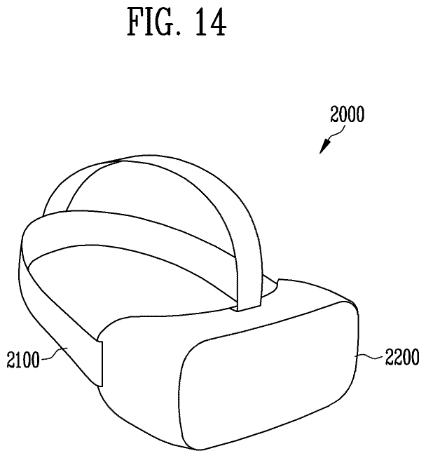

FIG. 14 illustrates schematic perspective view of an application example of the display system of FIG. 13.

Referring to FIG. 14, the display system 1000 of FIG. 13 may be applied to a head-mounted display device 2000. The head-mounted display device 2000 may be a wearable electronic device that may be worn on the user's head.

The head-mounted display device 2000 may include a head-mounted band 2100 and a display device accommodation case 2200. The head-mounted band 2100 may be connected to the display device accommodation case 2200. The head-mounted band 2100 may include a horizontal band and/or a vertical band for fixing the head-mounted display device 2000 to the user's head. The horizontal band may be configured to surround the side portion of the user's head, and the vertical band may be configured to surround the upper portion of the user's head. However, embodiments are not limited thereto. For example, the head-mounted band 2100 may be implemented in the form of a spectacle frame, a helmet, or the like.

The display device accommodation case 2200 may accommodate the first and second display devices 1210 and 1220 of FIG. 13. The display device accommodation case 2200 may further accommodate the processor 1100 of FIG. 13.

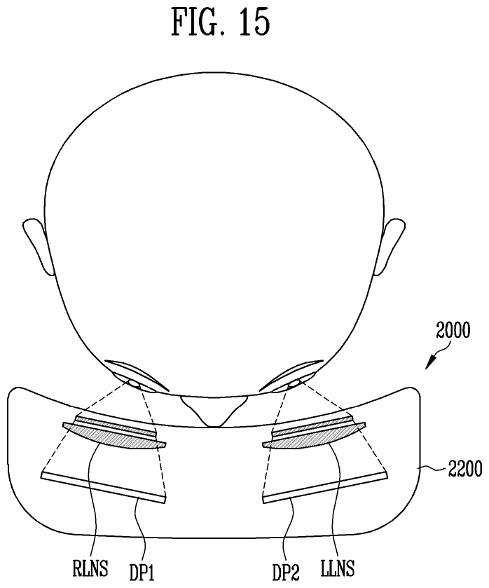

FIG. 15 illustrates a schematic head-mounted display device of FIG. 14 worn by an operator.

Referring to FIG. 15, a first display panel DPI of the first display device 1210 and a second display panel DP2 of the second display device 1220 are disposed in the head mounted display device 2000. The head-mounted display device 2000 may further include one or more lenses LLNS and RLNS.

In the display device accommodation case 2200, the right eye lens RLNS may be disposed between the first display panel DPI and the right eye of the operator. In the display device accommodation case 2200, the left eye lens LLNS may be disposed between the second display panel DP2 and the left eye of the operator.

An image outputted from the first display panel DP1 may be shown to the right eye of the operator through the right eye lens RLNS. The right eye lens RLNS may refract light from the first display panel DPI to be directed to the right eye of the operator. The right eye lens RLNS may perform an optical function to adjust the viewing distance between the first display panel DP1 and the right eye of the operator.

An image outputted from the second display panel DP2 may be shown to the left of the operator through the left eye lens LLNS. The left eye lens LLNS may refract light from the second display panel DP2 to be directed to the left eye of the operator. The left eye lens LLNS may perform an optical function to adjust the viewing distance between the second display panel DP2 and the left eye of the operator.

In embodiments, each of the right eye lens RLNS and the left eye lens LLNS may include an optical lens having a cross-section of a pancake shape. In the embodiments, each of the right eye lens RLNS and the left eye lens LLNS may include a multi-channel lens including sub-areas with different optical characteristics. For example, each display panel outputs images corresponding to the sub-areas of the multi-channel lens, and the output images may pass through the sub-areas and be viewed by the operator.

Subsequently, a manufacturing method of the display device according to the above-described embodiment will be described.

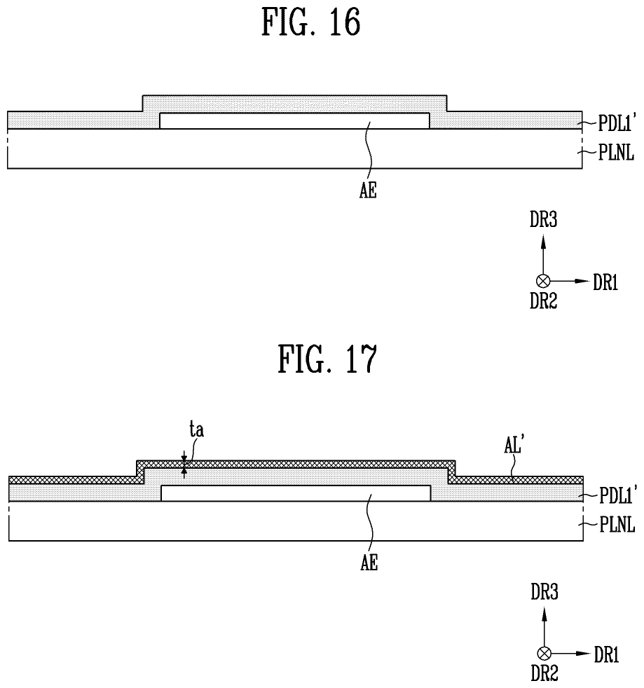

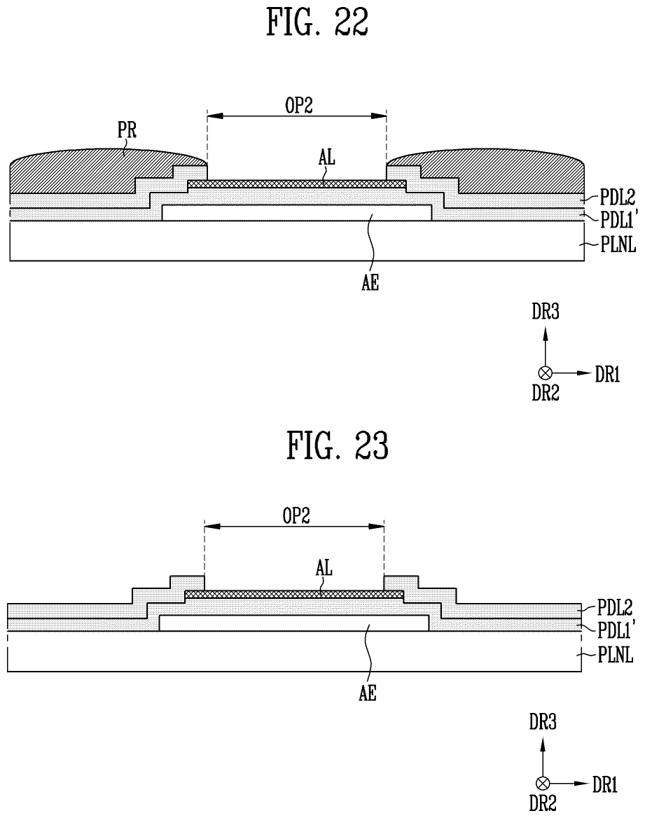

FIG. 16 to FIG. 26 illustrate schematic cross-sectional views of process steps of a manufacturing method of a display device according to an embodiment. FIG. 16 to FIG. 26 are schematic cross-sectional views for explaining a manufacturing method of the display device of FIG. 1 to FIG. 15, and are briefly shown for better understanding and ease of description, and detailed symbols therein are omitted.

Referring to FIG. 16, the anode electrode AE is formed on the planarization layer PLNL, and a first layer PDL1′ is formed on the anode electrode AE. The first layer PDL1′ may be made of at least one of a silicon oxide (SiOx) and a silicon nitride (SiNx), but is not limited thereto.

Referring to FIG. 17, a sacrificial layer AL′ is formed on the first layer PDL1′. The sacrificial layer AL′ may be made of aluminum or an aluminum alloy, but is not necessarily limited thereto, and the material of the sacrificial layer AL′ may be variously changed within a range that may be removed by wet etching. A thickness ta of the sacrificial layer AL′ in the third direction DR3 may be around 50 Å to around 500 Å, but is not necessarily limited thereto.

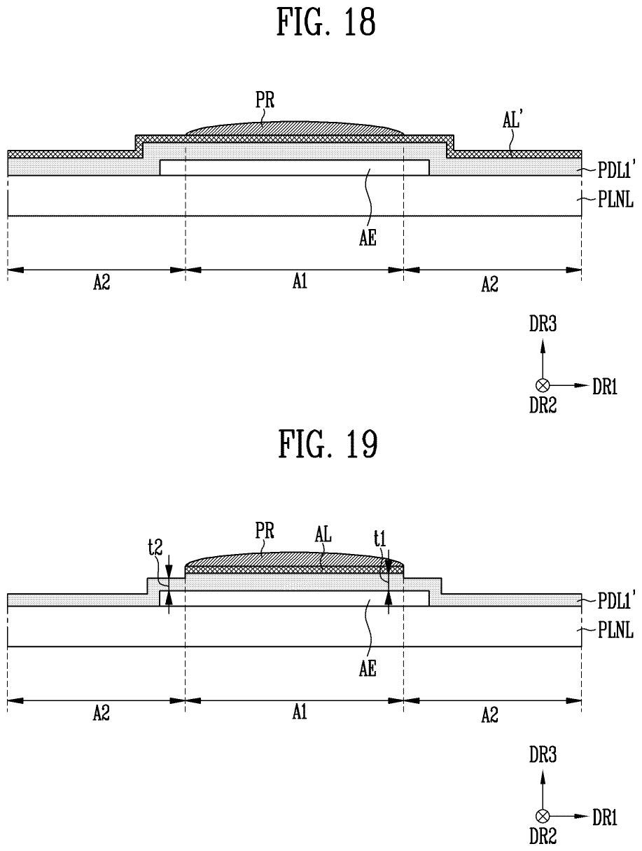

Referring to FIG. 18 and FIG. 19, a photoresist PR is at least partially formed on the sacrificial layer AL′ and the sacrificial layer AL′ is etched to form a sacrificial pattern AL. The photoresist PR may be formed at a position overlapping the first area A1 of the first layer PDL1′ in the third direction DR3. In the process of forming the sacrificial pattern AL by etching the sacrificial layer AL′, the second area A2 of the first layer PDL1′ exposed by the sacrificial pattern AL may be at least partially etched. Accordingly, the thickness t2 in the third direction DR3 of the second area A2 of the etched first layer PDL1′ may be formed to be thinner than the thickness t1 in the third direction DR3 of the first area A1 thereof.

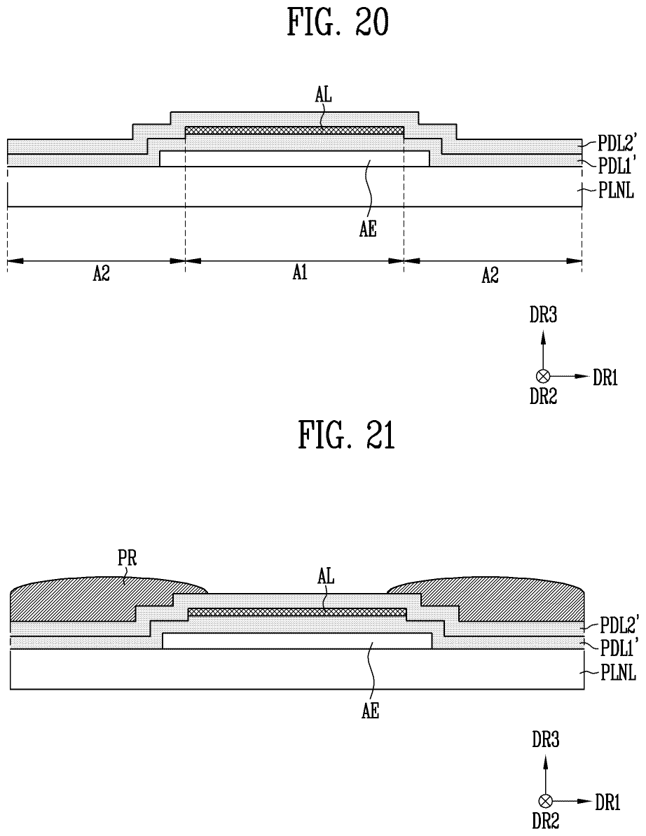

Referring to FIG. 20, a second layer PDL2′ is formed on the first layer PDL1′ and the sacrificial pattern AL. The second layer PDL2′ may be made of at least one of a silicon oxide (SiOx) and a silicon nitride (SiNx), but is not limited thereto. The second layer PDL2′ may cover the first layer PDL1′ exposed by the sacrificial pattern AL. The second layer PDL2′ may be directly formed on the second area A2 of the first layer PDL1′. The second layer PDL2′ may cover a side surface and an upper surface of the sacrificial pattern AL. The second layer PDL2′ may be directly formed on the side surface and the top surface of the sacrificial pattern AL, and the first layer PDL1′ may be directly formed on the sacrificial pattern AL.

Referring to FIG. 21 to FIG. 23, the second opening OP2 is formed in the second layer PDL2′ to form the second pixel defining film PDL2. After a photoresist PR is formed on the second layer PDL2′ and the second layer PDL2′ is etched to form the second opening OP2, the photoresist PR may be removed. The second opening OP2 may at least partially expose the sacrificial pattern AL. The width of the second opening OP2 in the first direction DR1 may be smaller than that of the sacrificial pattern AL in the first direction DR1.

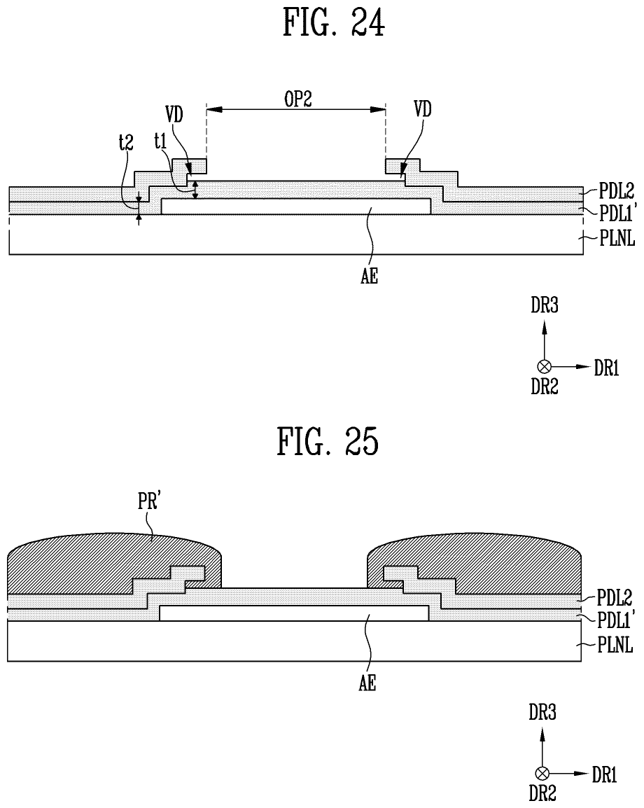

Referring to FIG. 24, the sacrificial pattern AL is then removed. The sacrificial pattern AL may be removed through the second opening OP2 of the second pixel defining film PDL2. To selectively etch the sacrificial pattern AL, the sacrificial pattern AL may be etched through a wet etching process. Even if the sacrificial pattern AL is etched, the first layer PDL1′ and the second pixel defining film PDL2 may not be removed by the wet etching solution. Accordingly, the thickness distribution of the first layer PDL1′ formed on the anode electrode AE may be minimized. A space formed by removing the sacrificial pattern AL between the first layer PDL1′ and the second pixel defining film PDL2 may form the void VD. The thickness t1 of the first layer PDL1′ overlapping the void VD in the third direction DR3 may be thicker than the thickness t2 of the first layer PDL1′ non-overlapping the void VD in the third direction DR3. As described above, in case that the sacrificial pattern AL formed between the first layer PDL1′ and the second pixel defining film PDL2 is removed to form the void VD, the width and thickness of the void VD may be easily adjusted using the sacrificial pattern AL, so that the process control ability may be improved.

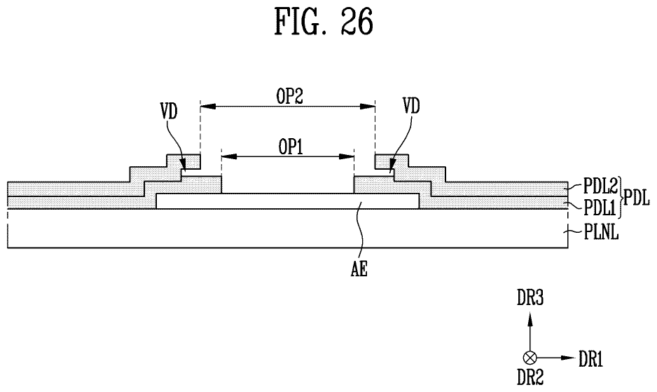

Referring to FIG. 25 and FIG. 26, the first opening OP1 is formed in the first layer PDL1′ to form the first pixel defining film PDL1. After a photoresist PR is formed on the first layer PDL1′ and the second pixel defining film PDL2 and the first layer PDL1′ is etched to form the first opening OP1, the photoresist PR may be removed. As described above, by forming the void VD using the sacrificial pattern AL, the thickness distribution of the first pixel defining film PDL1 formed on the anode electrode AE may be minimized. Accordingly, damage to the anode electrode AE may be minimized in the process of forming the first opening OP1 of the first pixel defining film PDL1. The first opening OP1 may at least partially expose the anode electrode AE. A width of the first opening OP1 in the first direction DR1 may be smaller than a width of the second opening OP2 in the first direction DR1. A width of the second opening OP1 in the first direction DR1 may be smaller than a width of the anode electrode AE. Subsequently, the light emitting structure EMS or the like may be formed on the anode electrode AE, the first pixel defining film PDL1, and the second pixel defining film PDL2 to complete the display device of FIG. 1 to FIG. 15.

However, the effects of the disclosure are not restricted to the one set forth herein. The above and other effects of the disclosure will become more apparent to one of daily skill in the art to which the disclosure pertains by referencing the claims. The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode;
a first pixel defining film disposed on the first electrode;
a second pixel defining film disposed on the first pixel defining film;
a void between an end of the first pixel defining film and an end of the second pixel defining film;
a light emitting structure disposed on the first electrode, the first pixel defining film, and the second pixel defining film; and
a second electrode disposed on the light emitting structure,
wherein a thickness of a first area of the first pixel defining film overlapping the void is thicker than a thickness of a second area of the first pixel defining film non-overlapping the void.

2. The display device of claim 1, wherein in the first area, the second pixel defining film is spaced apart from the first pixel defining film in a thickness direction.

3. The display device of claim 1, wherein in the second area, the second pixel defining film is in contact with the first pixel defining film.

4. The display device of claim 1, wherein
the first pixel defining film includes a first opening exposing the first electrode, and
the second pixel defining film includes a second opening exposing the first pixel defining film and the first electrode.

5. The display device of claim 4, wherein
a width of the second opening is greater than a width of the first opening in a plan view, and
a width of the second opening is less than a width of the first electrode in a plan view.

6. The display device of claim 1, wherein a thickness of the void in a thickness direction is about 50 Å to about 500 Å.

7. The display device of claim 1, wherein a lower surface of the void is defined by the first pixel defining film.

8. The display device of claim 1, wherein an upper surface of the void is defined by the second pixel defining film.

9. The display device of claim 1, wherein a side surface of the void is defined by the second pixel defining film.

10. The display device of claim 1, wherein the light emitting structure is at least partially separated by the void.

11. A manufacturing method of a display device, comprising:
forming a first layer disposed on a first electrode;
forming a sacrificial layer disposed on the first layer;
forming a sacrificial pattern by etching the sacrificial layer;
forming a second layer disposed on the first layer and the sacrificial pattern;
forming a second pixel defining film by forming a second opening in the second layer to expose the sacrificial pattern;
removing the sacrificial pattern through the second opening; and
forming a first pixel defining film by forming a first opening in the first layer to expose the first electrode,
wherein in the forming of the sacrificial pattern by etching the sacrificial layer, a portion of the first layer that does not overlap the sacrificial pattern is etched.

12. The manufacturing method of the display device of claim 11, wherein the second layer is directly formed on the first layer exposed by the sacrificial pattern.

13. The manufacturing method of the display device of claim 11, wherein a width of the second opening is smaller than a width of the sacrificial pattern in a plan view.

14. The manufacturing method of the display device of claim 11, wherein a width of the first opening is smaller than a width of the second opening in a plan view.

15. The manufacturing method of the display device of claim 11, wherein, in the removing of the sacrificial pattern, a void is formed between an end of the first layer and an end of the second pixel defining film.

16. The manufacturing method of the display device of claim 15, wherein a thickness of the first pixel defining film overlapping the void in a thickness direction is thicker than a thickness of the first pixel defining film that does not overlap the void in a thickness direction.

17. The manufacturing method of the display device of claim 15, further comprising:
forming a light emitting structure disposed on the first electrode exposed by the first opening.

18. The manufacturing method of the display device of claim 17, wherein the light emitting structure is at least partially separated by the void in a thickness direction.

19. The manufacturing method of the display device of claim 11, wherein the sacrificial layer is made of aluminum or an aluminum alloy.

20. The manufacturing method of the display device of claim 11, wherein a thickness of the sacrificial layer in a thickness direction is about 50 Å to about 500 Å.
